(19) United States
(12) Patent Application Publication
(10) Pub. No.: US 2025/0075795 A1
(43) Pub. Date: Mar. 6, 2025

(54) SEAL ASSEMBLY WITH A RETAINING MECHANISM

(71) Applicant: Applied Materials, Inc., Santa Clara, CA (US)

(72) Inventors: Jonathan SIMMONS, San Jose, CA (US); Andreas SCHMID, Meyriez (CH); Sahiti NALLAGONDA, Santa Clara, CA (US)

(21) Appl. No.: 18/523,111

(22) Filed: Nov. 29, 2023

Related U.S. Application Data
(60) Provisional application No. 63/535,047, filed on Aug. 28, 2023.

(51) Int. Cl. F16J 15/06; H01J 37/32

(52) U.S. Cl. CPC F16J 15/06; H01J 37/32513; H01J 2237/166

(57) ABSTRACT

Disclosed herein is a seal assembly for a substrate processing chamber and a component assembly containing the seal assembly. The seal assembly includes a ring-shaped seal member; a holder disposed radially inward of the ring-shaped seal member; and a retaining mechanism coupling the ring-shaped seal member with the holder. The component assembly includes a first component coupled with a second component via a bonding layer; a groove formed by the first component, the second component, and the bonding layer; and the seal assembly disposed in the groove.

### RELATED APPLICATIONS

The present application claims benefit to U.S. Provisional Application No. 63/535,047 filed Aug. 28, 2023, entitled “Seal Assembly with A Retaining Mechanism,” the content of which is hereby incorporated by reference in its entirety for all purposes.

### BACKGROUND

### Field

The present disclosure generally relates to relate to a substrate support assembly containing a seal assembly and, more particularly, relates a seal assembly with a retaining mechanism.

### Description of the Related Art

Semiconductor processing involve many corrosive processing gases, such as hydrogen fluoride, hydrogen chloride, silicon tetrafluoride, and phosphine. Mechanical and electrical parts, such as electrostatic chucks, showerheads, gas inlets, and chamber walls, in a substrate processing chamber need to be protected against corrosive processing gases. Seals are often used to separate chamber parts and components from processing gases. For example, electrostatic chucks are used to support substrates in a substrate processing chamber and are formed by several components. Any gaps or joints among components provide some access for processing gases to enter the internal part of an electrostatic chuck. A seal may be used to cover those gaps and joints and prevent gases from entering. However, seals may fail or even fall off after thermal cycling over time during substrate processing.

Accordingly, there is a needed to have an improved seal assembly for parts of a substrate processing chamber.

### SUMMARY

Disclosed herein are a seal assembly for a substrate processing chamber and a component assembly containing the seal assembly. The seal assembly includes a ring-shaped seal member; a holder disposed radially inward of the ring-shaped seal member; and a retaining mechanism coupling the ring-shaped seal member with the holder. The component assembly includes a first component coupled with a second component via a bonding layer; a groove formed by the first component, the second component, and the bonding layer; and the seal assembly disposed in the groove.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates a schematic top view of a processing system, according to an embodiment of the present application.

FIG. 2 illustrates a schematic cross-sectional view of a processing chamber containing a substrate support assembly, according to an embodiment of the present application.

FIG. 3a illustrates a schematic cross-sectional view of a substrate support assembly including a seal assembly, according to an embodiment.

FIG. 3b illustrates a schematic cross-sectional view of a showerhead including a seal assembly, according to an embodiment.

FIG. 4a illustrates a schematic top view of a seal assembly, according to an embodiment.

FIG. 4b illustrates a schematic top view of a holder of a seal assembly, according to an embodiment.

FIG. 5 illustrates a schematic cross-sectional view of a seal assembly, according to an embodiment.

FIG. 6a illustrates a schematic cross-sectional view of a seal assembly, according to an embodiment.

FIG. 6b illustrates a schematic cross-sectional view of a seal assembly, according to an embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

Disclosed herein are a seal assembly and a substrate support assembly containing the seal assembly. The seal assembly includes a seal member and a holder. The seal member is disposed radially outward to the holder to prevent corrosive gases from contacting the holder. The seal member and the holder are coupled via a retaining mechanism. The retaining mechanism includes protrusions disposed in a direction that hinders shifting of the seal member. With this configuration, the seal member can be held in place by the holder even after the seal member has been subjected to many thermal cycles.

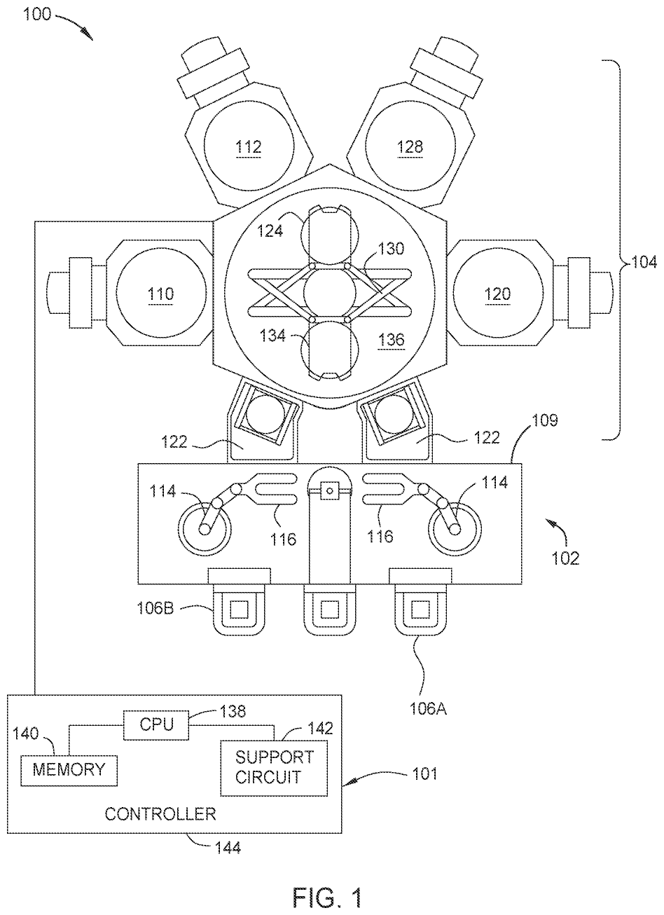

FIG. 1 illustrates a schematic top view of a processing system 100, according to one or more embodiments. The processing system 100 includes one or more load lock chambers 122 (two are shown in FIG. 1), a processing platform 104, a factory interface 102, and a controller 144. In one or more embodiments, the processing system 100 is a CENTURA® integrated processing system, commercially available from Applied Materials, Inc., located in Santa Clara, California. It is contemplated that other processing systems (including those from other manufacturers) may be adapted to benefit from the disclosure.

The processing platform 104 includes a plurality of processing chambers 110, 112, 120, 128, the one or more load lock chambers 122, and a transfer chamber 136 that is coupled to the one or more load lock chamber 122. The transfer chamber 136 can be maintained under vacuum, or can be maintained at an ambient (e.g., atmospheric) pressure. Two load lock chambers 122 are shown in FIG. 1. The factory interface 102 is coupled to the transfer chamber 136 through the load lock chambers 122. According to an embodiment, each one of the plurality of processing chambers 110, 112, 120, and 128 may be a low temperature EPI chamber as set forth in the present application.

In one or more embodiments, the factory interface 102 includes at least one docking station 109 and at least one factory interface robot 114 to facilitate the transfer of substrates 124. The docking station 109 is configured to accept one or more front opening unified pods (FOUPs). Two FOUPS 106A, 106B are shown in the implementation of FIG. 1. The factory interface robot 114 having a blade 116 disposed on one end of the robot 114 is configured to transfer one or more substrates from the FOUPS 106A, 106B, through the load lock chambers 122, to the processing platform 104 for processing. Substrates being transferred can be stored at least temporarily in the load lock chambers 122.

Each of the load lock chambers 122 has a first port interfacing with the factory interface 102 and a second port interfacing with the transfer chamber 136. The load lock chambers 122 are coupled to a pressure control system (not shown) which pumps down and vents the load lock chambers 122 to facilitate passing the substrates between the environment (e.g., vacuum environment or ambient environment, such as atmospheric environment) of the transfer chamber 136 and a substantially ambient (e.g., atmospheric) environment of the factory interface 102.

The transfer chamber 136 has a vacuum robot 130 disposed therein. The vacuum robot 130 has one or more blades 134 (two are shown in FIG. 1) capable of transferring the substrates 124 between the load lock chambers 122 and the processing chambers 110, 112, 120, and 128.

The controller 144 is coupled to the processing system 100 and is used to control processes and methods, such as the operations of the methods described herein (for example the operations of the methods as described in other parts of the present application). The controller 144 includes a central processing unit (CPU) 138, a memory 140 containing instructions, and support circuits 142 for the CPU. The controller 144 controls various items directly, or via other computers and/or controllers.

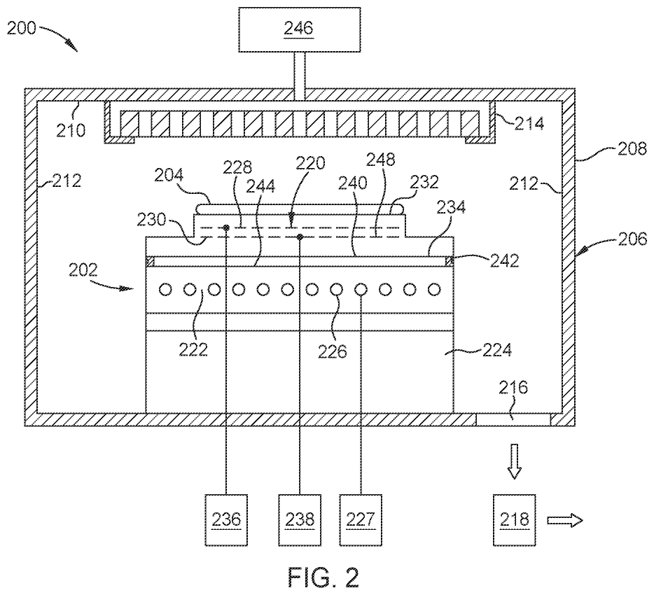

FIG. 2 illustrates a schematic view of a substrate processing chamber 200 according to an embodiment. The substrate processing chamber 200 may be any one of the chambers 110, 112, 128, and 120 as shown in FIG. 1. The substrate processing chamber 200 includes a substrate support assembly 202 that supports a substrate 204. The substrate processing chamber 200 further includes a chamber body 206 having walls 208 and a lid 210 that enclose a processing region 212. A gas inlet 214 is coupled to the walls 208 and/or lid 210 of the chamber body 206 and provides processing gases from a gas source 246 into the processing region 212. The gas inlet 214 may be one or more nozzles or inlet ports, or alternatively a showerhead. Processing gases, along with any processing by-products, are removed from the processing region 212 through an exhaust port 216. The exhaust port 216 is coupled to a pumping system 218, which includes throttle valves and pumps utilized to control the vacuum levels within the processing region 212.

The substrate support assembly 202 is disposed in the processing region 212 below the gas inlet 214. The substrate support assembly 202 includes an electrostatic chuck 220 and a cooling plate 222. The cooling plate 222 is supported by a base plate 224.

The cooling plate 222 may be formed from a metal material or other suitable material. For example, the cooling plate 222 may be formed from aluminum (Al). The cooling plate 222 may include cooling channels 226 formed therein. The cooling channels 226 may be connected to a heat transfer fluid source 227. The heat transfer fluid source 227 provides a heat transfer fluid, such as a liquid, gas or combination thereof, which is circulated through one or more cooling channels 226.

The electrostatic chuck 220 includes chucking electrodes 228 disposed in a dielectric body 230. The chucking electrodes 228 are coupled with a power source 236. The electrostatic chuck 220 may include any optional heater electrode 248 coupled with a power source 238. The dielectric body 230 has a support surface 232 and a bottom surface 234 opposite the support surface 232. The dielectric body 230 of the electrostatic chuck 220 may be fabricated from a ceramic material, aluminum nitride, a polymer, such as polyimide, polyetheretherketone, and polyaryletherketone, or any other suitable materials.

A bonding layer 240 is disposed between the electrostatic chuck 220 and the cooling plate 222. The bonding layer 240 may be formed from a single layer of adhesive or several layers which provide for different thermal expansions of the electrostatic chuck 220 and the cooling plate 222. The bonding layer 240 forms a joint 244 between the cooling plate 222 and the electrostatic chuck 220. According to an embodiment, the bonding layer 240 is protected by a seal assembly 242 as set forth in the present application. The seal assembly 242 is configured to protect the bonding layer 240 and the joint 244 from the processing gases present in the substrate processing chamber 200.

According to an embodiment, a showerhead included in the gas inlet 214 also includes a seal assembly as set forth in the present application. According to an embodiment, a joint between the lid 210 and the walls 208 also includes a seal assembly as set forth in the present application.

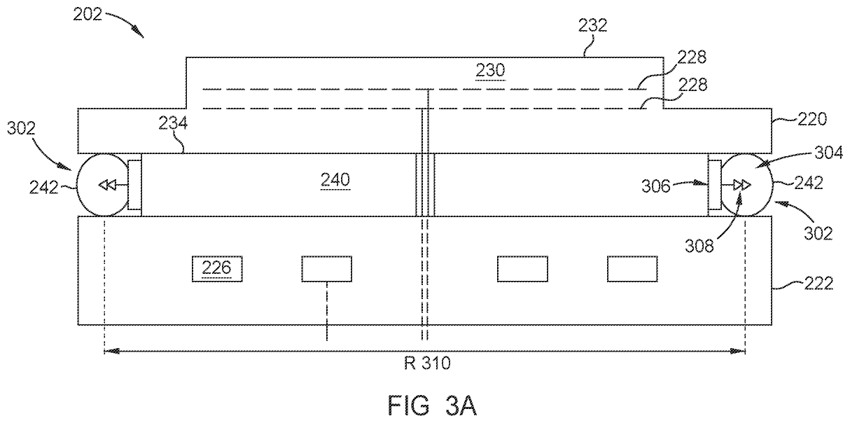

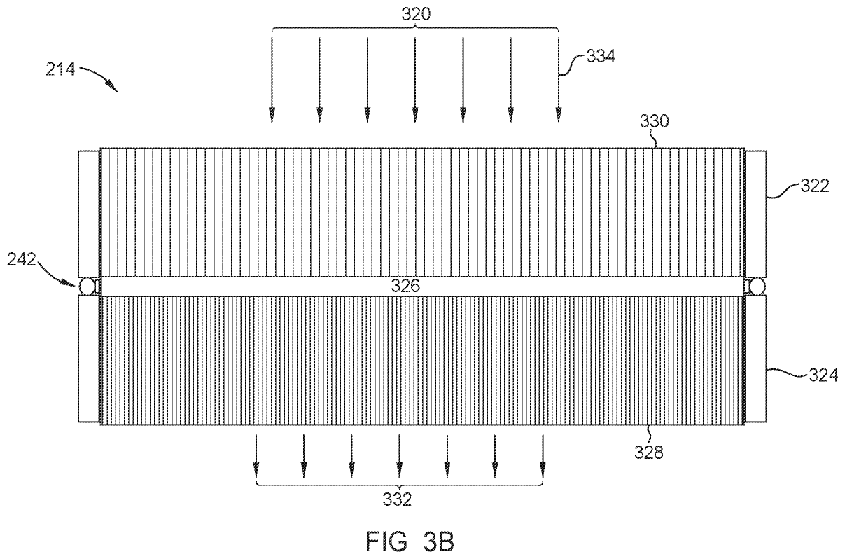

FIG. 3a illustrates a schematic cross-sectional view of the substrate support assembly 202 containing the seal assembly 242 disposed between an electrostatic chuck 220 and the cooling plate 222, according to an embodiment. A groove 302 is formed by the electrostatic chuck 220, the bonding layer 240, and the cooling plate 222. The seal assembly 242 resides in the groove 302 and circumscribes the outer periphery of the bonding layer 240. The seal assembly 242 may be in the form of a circle with a diameter R 310. The diameter R 310 of the seal assembly 242 is less than the outer diameter of the electrostatic chuck 220 and the cooling plate 222.

In one embodiment, the seal assembly 242 prevents the processing gas from contacting the bonding layer 240 of the substrate support assembly 126. The seal assembly 242 also protects the inner portions of the substrate support assembly 202 from exposure to the plasma environment.

According to an embodiment, the seal assembly 242 includes a seal member 304, a holder 306, and a retaining mechanism 308. The seal member 304 prevents the corrosive processing gases from contacting the holder 306 and/or the bonding layer 240. The holder 306 and the retaining mechanism 308 are configured to hold the seal member 304 in place when substrates 204 are processed. The holder 306 and the retaining mechanism 308 increase the work life of the seal member 304 before it needs to be replaced.

The seal member 304 has an outer diameter. The outer diameter is a gas-exposing side, where the seal member 304 is exposed to processing gases when substrates are processed within the substrate processing chamber 200. To avoid being attacked by the processing gases, the holder 306 and the retaining mechanism 308 are coupled with the seal member 304 along an inner diameter of the seal member 304 that is opposite to the gas-exposing side.

The material of the seal member 304 is selected to be compatible with the corrosive processing and/or etching gases used in the substrate processing chamber 200. The seal member 304 may be formed from a soft elastomeric material, such as fluoroelastomers or silicon elastomers, or other suitable materials. The seal member 304 may be formed from a high performance elastomer, a perfluoroelastomer such as Fluoritz-TR® or Perlast G67P®, or other suitable material.

The seal member 304 may have various shapes. For example, the seal member 304 may be an O-ring. The seal member may also have a V-shaped cross-section or a square cross-section or any other suitable cross-sections.

The material of the holder 306 may be a metal, plastic, or any other suitable materials. In one example, the holder 306 may be made of stainless steel or aluminum. The plastic material may include fluorinated ethylene propylene, polyether ether ketone, or polytetrafluoroethylene.

The retaining mechanism 308 may be an integral part of the holder 306. Alternatively, the retaining mechanism 308 may also be an integral part of the seal member 304. In other examples, the retaining mechanism 308 may be include complimentary structures that are part of the seal member 304 and the holder 306.

FIG. 3b illustrates a schematic cross-sectional view of a showerhead 214 having a seal assembly, according to an embodiment. The showerhead 214 includes a first component 322 coupled with a second component 324 via a bonding layer 326. The first component 322 includes a plurality of conduits 330 configured to receive processing gases 334 from a plenum 320. The second component 324 includes a plurality micro dispensing ports 328 configured to distribute the processing gas 334 into a region 332 above the substrate support assembly 202. According to an embodiment, the first component 322, the second component 324, and the bonding layer 326 form a groove, in which the seal assembly 242 is disposed.

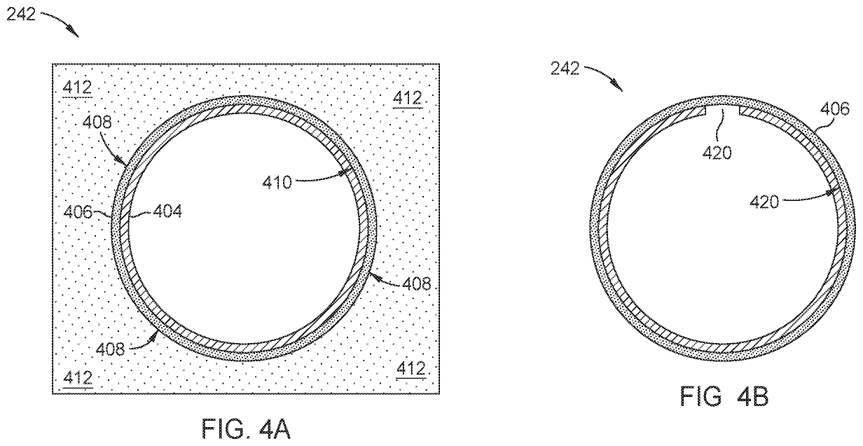

FIG. 4a illustrates a schematic top view of a seal assembly 242, according to an embodiment. A seal member 406 has an outer diameter 408 that contacts processing gases 412. The seal member 406 also has an inner diameter 410 that is opposite to the outer diameter 408. A holder 404 is disposed radially inward of the seal member 406 and coupled with the seal member 406 along the inner diameter 410. A retaining mechanism 308 is disposed along the inner diameter 410.

According to an embodiment as shown in FIG. 4a, both the holder 404 and the seal member 406 represent enclosed circles. According to an embodiment as shown in FIG. 4b, a holder 420 that can be used with the seal assembly 242 includes a cutout area 422 to facility the installation of the holder 420 onto the substrate support assembly 202.

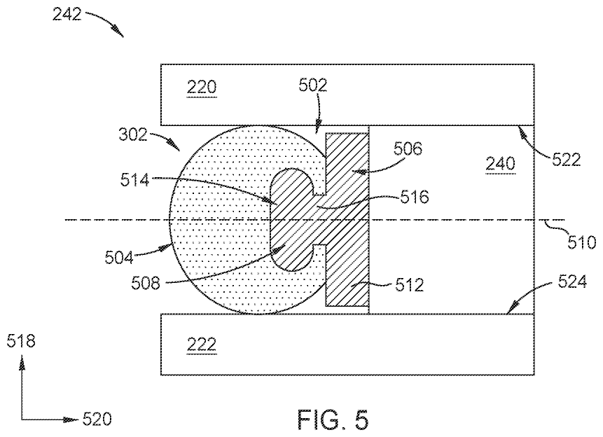

FIG. 5 illustrates a schematic cross-sectional view of a seal assembly 242, according to an embodiment. As stated above, the electrostatic chuck 220, the bonding layer 240, and the cooling plate 222 form the groove 302. The seal assembly 242 is disposed inside the groove 302. The seal assembly 242 includes a seal member 504 and a holder 506. According to an embodiment, the seal member 504 is ring-shaped. The seal member 504 may have a symmetrical cross-section. The seal member 504 has a height that is slightly greater than the groove. The seal member 504 is configured to contact a bottom surface 522 of the electrostatic chuck 220 and a top surface 524 of the cooling plate 222 to prevent processing gases from contacting the bonding layer 240. The seal member 504, the electrostatic chuck 220, the bonding layer 240, and the cooling plate 222 form a chamber 502, in which the holder 506 is disposed. The holder 506 includes a base 512 and a protrusion 516. The base 512 conforms to the circumference of the bonding layer 240. The protrusion 516 is configured to interlock with a mating depression of the seal member 504, thus retaining the seal member 504 and preventing the seal member 504 from moving radially outward. The protrusion 516 and the depression form the retaining mechanism.

To prevent the seal member 504 from moving in a horizontal direction 520 toward an opening of the groove 302, the protrusion 516 includes extensions 514 disposed along a vertical direction 518 to stop the seal member 504 from shifting horizontally. According to an embodiment, the extensions 514 and the base 512 are both aligned vertically and parallel with each other. According to an embodiment, both the seal member 504 and the holder 506 have a symmetrical shape. For example, the seal member 504 may have a substantially circular shape. The holder 506 may have an H-shaped cross-section with one leg shorter than the other. The seal member 504 and the holder 506 may be centrally aligned along a common axis 510.

The retaining mechanism 308 of the seal assembly 500 may include a protrusion and a mating depression. The placement of the protrusion or the mating depression is not limited to any particular part. For example, the protrusion may be disposed in the holder 506 or the seal member 504. Similarly, the mating depression may be also disposed in the holder 506 or the seal member 504 depending on the placement of the protrusion.

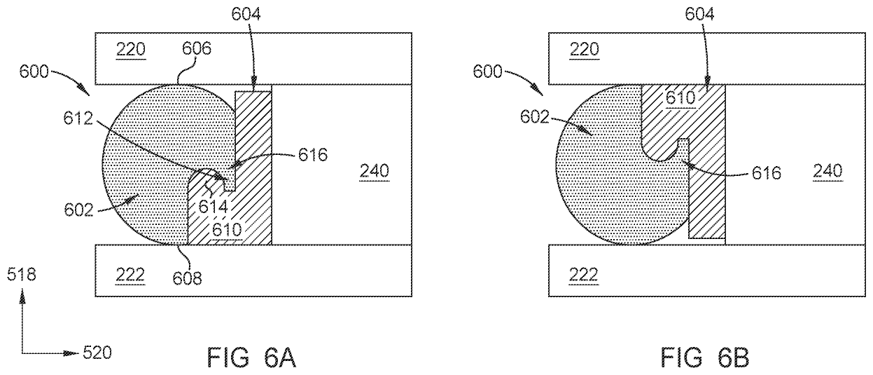

FIG. 6a illustrates a schematic cross-sectional view of a seal assembly 600, according to an embodiment. The seal assembly 600 includes a seal member 602 interlocked with a holder 604. The holder 604 includes a J-shaped hook 610. The J-shaped hook 610 includes an extension 614 extending along a vertical direction and an opening 616 facing toward the electrostatic chuck 220. Comparing with the seal assembly 500 of FIG. 5, the seal assembly 600 has an asymmetrical cross-section. The seal member 602 includes a finger 612 that engages with the opening 616 of the J-shaped hook 610 to retain the seal member 602 to the holder 604.

According to an embodiment, the seal assembly 600 is configured to counter an initial shift of a seal member caused by thermal expansion. As the electrostatic chuck 220 includes heating electrodes 228 and the cooling plate 222 includes cooling channels 226, a temperature gradient may be formed along a vertical direction 518, where the temperature declines from a bottom surface 606 of the electrostatic chuck 220 to a top surface 608 of the cooling plate 222. Due to the temperature gradient, the seal member 602 may start shifting by moving toward the cooler side first. By orienting the J-shaped hook 610 adjacent to the cooling plate 222 and facing the opening 616 toward the electrostatic chuck 220, i.e. along a temperature rising direction, the finger 612 expands into the opening 616, where the extension 614 locks the seal member 602 in place. The height of the groove 302 prevents the finger 612 from disengaging the J-shaped hook 610.

According to another embodiment shown in FIG. 6b, the J-shaped hook 610 may be disposed adjacent to the electrostatic chuck 220 with the opening 616 facing the cooling plate 222.

Similar with the seal assembly shown in FIG. 6a, the seal member 602 of FIG. 6b is configured to have sections that match the J-shaped hook of the holder 604. For example, the seal member 602 includes depressions that mate with the extension 614. The seal member 602 also includes a finger that mates with the opening 616.

It is contemplated that one or more aspects disclosed herein may be combined. Moreover, it is contemplated that one or more aspects disclosed herein may include some or all of the aforementioned benefits. While the foregoing is directed to embodiments of the present disclosure, other and further embodiments of the disclosure may be devised without departing from the basic scope thereof, and the scope thereof is determined by the claims that follow.

What is claimed is:

1. A seal assembly for a substrate processing chamber, comprising:
a ring-shaped seal member;
a holder disposed radially inward of the ring-shaped seal member; and
a retaining mechanism coupling the ring-shaped seal member with the holder.

2. The seal assembly of claim 1, wherein the seal member is made of an elastomer, and the holder is made of a plastic material or a metal.

3. The seal assembly of claim 2, wherein the elastomer comprises a fluoroelastomer or a silicon elastomer.

4. The seal assembly of claim 3, wherein the plastic material comprises fluorinated ethylene propylene, polyether ether ketone, or polytetrafluoroethylene.

5. The seal assembly of claim 3, wherein the holder comprises stainless steel or aluminum.

6. The seal assembly of claim 1, wherein the ring-shaped seal member comprises an outer diameter configured to face processing gases contained in the substrate processing chamber and an inner diameter, and the ring-shaped seal member and the holder are coupled along the inner diameter.

7. The seal assembly of claim 6, wherein the ring-shaped seal member has a greater height than a height of the holder.

8. The seal assembly of claim 6, wherein the ring-shaped seal member comprises a symmetrical cross-section.

9. The seal assembly of claim 1, wherein the retaining mechanism comprises a protrusion mating with a depression.

10. The seal assembly of claim 9, wherein the protrusion is disposed in the holder, and the depression is disposed in the ring-shaped seal member.

11. The seal assembly of claim 9, wherein the protrusion is disposed in the ring-shaped seal member, and the depression is disposed in the holder.

12. The seal assembly of claim 9, wherein the holder comprise a J-shaped hook.

13. The seal assembly of claim 12, wherein the ring-shaped seal member comprises a finger that mates with an opening of the J-shaped hook of the holder.

14. A component assembly for a substrate processing chamber, comprising:
a first component coupled with a second component via a bonding layer;
a groove formed by the first component, the second component, and the bonding layer; and
a seal assembly disposed in the groove and comprising:
a ring-shaped seal member;
a holder disposed radially inward of the ring-shaped seal member; and
a retaining mechanism coupling the ring-shaped seal member with the holder.

15. The component assembly of claim 14, wherein the ring-shaped seal member comprises an outer diameter configured to face processing gases contained in the substrate processing chamber and an inner diameter, and the ring-shaped seal member and the holder are coupled along the inner diameter.

16. The component assembly of claim 14, wherein the ring-shaped seal member comprises a symmetrical cross-section.

17. The component assembly of claim 14, wherein the retaining mechanism comprises a protrusion mating with a depression, the protrusion is disposed in the holder, and the depression is disposed in the ring-shaped seal member.

18. The component assembly of claim 14, wherein the retaining mechanism comprises a protrusion mating with a depression, the protrusion is disposed in the ring-shaped seal member, and the depression is disposed in the holder.

19. The component assembly of claim 14, wherein the holder comprises a J-shaped hook, and an opening of the J-shaped hook faces toward a temperature rising direction.

20. The component assembly of claim 14, wherein the holder comprises a J-shaped hook, and an opening of the J-shaped hook faces toward a temperature declining direction.
